(19) United States
(12) Patent Application Publication
(10) Pub. No.: US 2026/0107614 A1
(43) Pub. Date: Apr. 16, 2026

(54) LIGHT EMITTING DEVICE AND DISPLAY DEVICE INCLUDING THE SAME

(71) Applicant: SAMSUNG ELECTRONICS CO., LTD., Suwon-si (KR)

(72) Inventors: Dongchul Shin, Suwon-si (KR); Joosung Kim, Suwon-si (KR); Junghun Park, Suwon-si (KR); Youngtek Oh, Suwon-si (KR); Kyungwook Hwang, Suwon-si (KR)

(73) Assignee: SAMSUNG ELECTRONICS CO., LTD., Suwon-si (KR)

(21) Appl. No.: 19/253,223

(22) Filed: Jun. 27, 2025

(30) Foreign Application Priority Data
Oct. 10, 2024 (KR) 10-2024-0138021

(51) Int. Cl. H10H 29/80; H10H 20/825

(52) U.S. Cl. CPC H10H 29/8321; H10H 20/825

(57) ABSTRACT

A light emitting device may include a first epitaxial structure, a first intermediate layer, a second epitaxial structure, a second intermediate layer, and a third epitaxial structure, which are sequentially stacked. A first p-type electrode, provided in a first via hole that penetrates the second epitaxial structure and the third epitaxial structure, may be in contact with the first intermediate layer, and a second p-type electrode, provided in a second via hole that penetrates the third epitaxial structure, may be in contact with the second intermediate layer.

### CROSS-REFERENCE TO RELATED APPLICATION

This application is based on and claims priority under 35 U.S. C. § 119 to Korean Patent Application No. 10-2024-0138021, filed on Oct. 10, 2024, in the Korean Intellectual Property Office, the disclosure of which is incorporated by reference herein in its entirety.

### BACKGROUND

### 1. Field

Embodiments of the disclosure relate to a light emitting device and a display device including the same.

### 2. Description of Related Art

In a monolithic light source, light sources may be arranged horizontally or vertically. By arranging the light sources vertically, the device size may be increased compared to arranging the same horizontally at a fixed resolution, and overall device performance may be improved.

However, in order to form n-electrodes and p-electrodes for each vertically stacked red (R)/green (G)/blue (B) light source, electrode via holes may need to be created using a dry etching process. This process may damage the p-type semiconductor, and thus electrical characteristics of the device may be deteriorated. Therefore, an improved vertical stacking manufacturing process is required to minimize damage caused by the electrode formation process and to improve the efficiency of the device.

### SUMMARY

According to embodiments of the disclosure, a light emitting device with improved efficiency and a display device including the same may be provided.

According to embodiments of the disclosure, a light emitting device may be provided and include: a first epitaxial structure, a second epitaxial structure, and a third epitaxial structure that are sequentially stacked; a first intermediate layer between the first epitaxial structure and the second epitaxial structure; a second intermediate layer between the second epitaxial structure and the third epitaxial structure; a first via hole penetrating the second epitaxial structure and the third epitaxial structure; a second via hole penetrating the third epitaxial structure; a first p-type electrode in the first via hole; and a second p-type electrode in the second via hole, wherein each of the first epitaxial structure, the second epitaxial structure, and the third epitaxial structure includes a first semiconductor layer of a first conductivity type, an active layer, and a second semiconductor layer of a second conductivity type, wherein the first epitaxial structure, the active layer, and the second semiconductor layer are sequentially stacked, and wherein the first p-type electrode is in contact with the first intermediate layer, and the second p-type electrode is in contact with the second intermediate layer.

According to one or more embodiments of the disclosure, the first intermediate layer may have a first thickness in a first direction, perpendicular to an extending direction of the first epitaxial structure, in a contact region in which the first intermediate layer is in contact with the first p-type electrode, and wherein the first thickness may be less than a second thickness of the first intermediate layer in a region in which the first intermediate layer does not contact the first p-type electrode.

According to one or more embodiments of the disclosure, the second intermediate layer may have a first thickness in a first direction, perpendicular to an extending direction of the second epitaxial structure, in a contact region in which the second intermediate layer is in contact with the second p-type electrode, and wherein the first thickness may be less than a second thickness of the second intermediate layer in a region in which the second intermediate layer does not contact the second p-type electrode.

According to one or more embodiments of the disclosure, the light-emitting device may further include a p-type contact semiconductor layer, wherein the p-type contact semiconductor layer is in a contact region in which the first intermediate layer is in contact with the first p-type electrode.

According to one or more embodiments of the disclosure, the p-type contact semiconductor layer may include a material that is the same as a material of the second semiconductor layer of the first epitaxial structure.

According to one or more embodiments of the disclosure, the light emitting device may further include a p-type contact semiconductor layer, wherein the p-type contact semiconductor layer is in a contact region in which the second intermediate layer is in contact with the second p-type electrode.

According to one or more embodiments of the disclosure, the p-type contact semiconductor layer may include a material that is the same as a material of the second semiconductor layer of the second epitaxial structure.

According to one or more embodiments of the disclosure, the first intermediate layer and the second intermediate layer may include AlGaN.

According to one or more embodiments of the disclosure, the light emitting device may further include a third p-type electrode on the third epitaxial structure.

According to one or more embodiments of the disclosure, the light emitting device may further include an n-type electrode extending upward from a lower portion of the first epitaxial structure.

According to one or more embodiments of the disclosure, the light emitting device may further include an n-type electrode extending downward from an upper portion of the third epitaxial structure.

According to one or more embodiments of the disclosure, the light emitting device may further include: a first insulating layer surrounding a sidewall of the first p-type electrode; and a second insulating layer surrounding a sidewall of the second p-type electrode.

According to embodiments of the disclosure, a light emitting device may be provided and include: a first epitaxial structure, a second epitaxial structure, and a third epitaxial structure that are sequentially stacked; a first intermediate layer between the first epitaxial structure and the second epitaxial structure; a second intermediate layer between the second epitaxial structure and the third epitaxial structure; a first via hole penetrating the second epitaxial structure and the third epitaxial structure; a second via hole penetrating the third epitaxial structure; a first p-type contact semiconductor layer in the first via hole; and a second p-type contact semiconductor layer in the second via hole, wherein each of the first epitaxial structure, the second epitaxial structure, and the third epitaxial structure includes a first semiconductor layer of a first conductivity type, an active layer, and a second semiconductor layer of a second conductivity type, wherein the first epitaxial structure, the active layer, and the second semiconductor layer are sequentially stacked, and wherein the first p-type contact semiconductor layer is in contact with the first intermediate layer, and the second p-type contact semiconductor layer is in contact with the second intermediate layer.

According to one or more embodiments of the disclosure, the first intermediate layer may have a first thickness in a first direction, perpendicular to an extending direction of the first epitaxial structure, in a contact region in which the first intermediate layer is in contact with the first p-type contact semiconductor layer, and wherein the first thickness may be less than a second thickness of the first intermediate layer in a region in which the first intermediate layer is not in contact with the first p-type contact semiconductor layer.

According to one or more embodiments of the disclosure, the second intermediate layer may have a first thickness in a first direction, perpendicular to an extending direction of the second epitaxial structure, in a contact region in which the second intermediate layer is in contact with the second p-type contact semiconductor layer, and wherein the first thickness may be less than a second thickness of the second intermediate layer in a region in which the second intermediate layer is not in contact with the second p-type contact semiconductor layer.

According to one or more embodiments of the disclosure, the light emitting device may further include: a first p-type electrode on the first p-type contact semiconductor layer; and a second p-type electrode on the second p-type contact semiconductor layer.

According to one or more embodiments of the disclosure, the first intermediate layer and the second intermediate layer may include AlGaN.

According to one or more embodiments of the disclosure, the light emitting device may further include an n-type electrode extending upward from a lower portion of the first epitaxial structure.

According to embodiments of the disclosure, a display device may be provided and include the light emitting device and a driving layer configured to drive the light emitting device.

According to one or more embodiments of the disclosure, the display device may further include a reflective electrode between the light emitting device and the driving layer.

Additional aspects of the disclosure will be set forth in part in the description which follows and, in part, will be apparent from the description, or may be learned by practice of the example embodiments of the disclosure.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view illustrating a display device according to an embodiment;

FIG. 2 is a cross-sectional view illustrating a modified example of a portion A of the light emitting device shown in FIG. 1;

FIG. 3 is a cross-sectional view illustrating a modified example of the portion A of the light emitting device shown in FIG. 1;

FIG. 4 is a cross-sectional view illustrating a display device according to an embodiment;

FIGS. 5A to 5J are cross-sectional views illustrating a method of manufacturing a display device, according to an embodiment;

FIG. 6 is a block diagram illustrating a schematic configuration of a display device according to an embodiment;

FIG. 7 is a schematic block diagram of an electronic device according to an embodiment;

FIG. 8 illustrates an example in which a display device according to an embodiment is applied to a mobile device;

FIG. 9 illustrates an example in which a display device according to an embodiment is applied to a display device for a vehicle;

FIG. 10 illustrates an example in which a display device according to an embodiment is applied to augmented reality glasses or virtual reality glasses;

FIG. 11 illustrates an example in which a display device according to an embodiment is applied to signage; and

FIG. 12 illustrates an example in which a display device according to an embodiment is applied to a wearable display.

### DETAILED DESCRIPTION

Reference will now be made in detail to non-limiting example embodiments of the disclosure, examples of which are illustrated in the accompanying drawings, wherein like reference numerals refer to like elements throughout. In this regard, embodiments of the disclosure may have different forms and should not be construed as being limited to the descriptions set forth herein. Accordingly, the example embodiments are merely described below, by referring to the figures, to explain example aspects of the disclosure. As used herein, the term “and/or” includes any and all combinations of one or more of the associated listed items. Expressions such as “at least one of,” when preceding a list of elements, modify the entire list of elements and do not modify the individual elements of the list.

Hereinafter, a light emitting device and a display device including the same according to various non-limiting example embodiments of the disclosure will be described in detail with reference to the accompanying drawings. In the drawings, the same or similar reference numerals refer to the same or similar components, and the size of each component in the drawings may be exaggerated for clarity and convenience of description. In addition, the example embodiments described below are merely illustrative, and various modifications are possible from these embodiments.

Hereinafter, the term “upper portion” or “on” may also include “to be present on the top, bottom, left, or right portion on a non-direct contact basis” as well as “to be present just on the top, bottom, left or right portion in directly contact with”. Singular expressions include plural expressions unless the context clearly means otherwise. In addition, when a part “includes” (or “comprises”) a component, this means that it may further include other components, rather than excluding other components, unless otherwise stated.

The use of the term “the” and similar indicative terms may correspond to both singular and plural. Unless there is clear order or contrary description of the steps constituting the method, these steps may be performed in the appropriate order, and are not necessarily limited to the order described.

The connection or connection members of lines between the components shown in the drawings represent example functional connections and/or physical or circuit connections, and may be replaceable or represented as various additional functional connections, physical connections, or circuit connections in an actual device.

The use of all examples and illustrative terms is simply to describe non-limiting example embodiment of the disclosure in detail, and the scope of the disclosure is not limited due to these examples and illustrative terms.

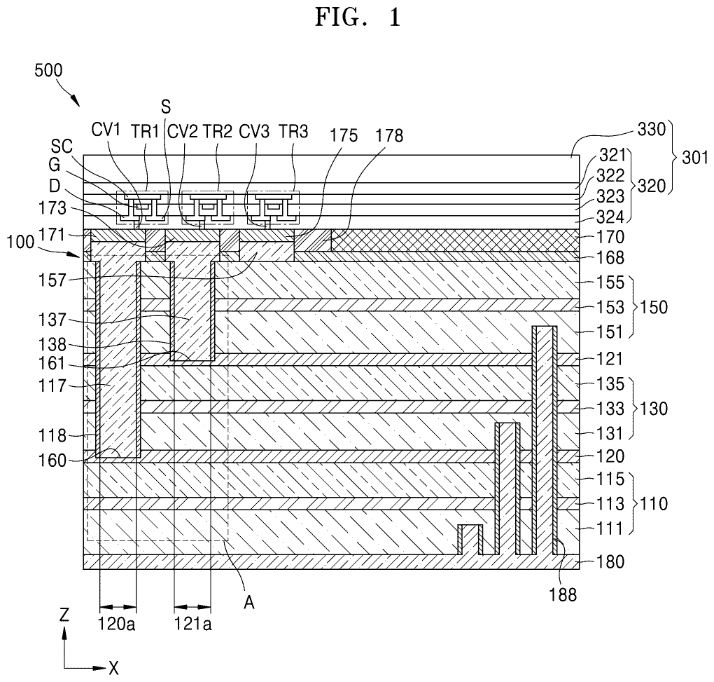

FIG. 1 is a cross-sectional view illustrating a display device according to an embodiment.

Referring to FIG. 1, a display device 500 may include a light emitting device 100, a driving layer 320 for driving the light emitting device 100, and a substrate 330 for supporting the driving layer 320. The driving layer 320 and the substrate 330 may be collectively referred to as a backplane 301.

The light emitting device 100 may include a first epitaxial structure 110, a second epitaxial structure 130, and a third epitaxial structure 150 that are sequentially stacked in a vertical direction, a first intermediate layer 120 provided between the first epitaxial structure 110 and the second epitaxial structure 130, a second intermediate layer 121 provided between the second epitaxial structure 130 and the third epitaxial structure 150, a first via hole 160 penetrating a portion of the second epitaxial structure 130 and a portion of the third epitaxial structure 150, a second via hole 161 penetrating a portion of the third epitaxial structure 150, a first p-type electrode 117 provided to fill the first via hole 160, and a second p-type electrode 137 provided to fill the second via hole 161.

The first epitaxial structure 110 may include a structure in which a first semiconductor layer 111 of a first conductivity type, an active layer 113, and a second semiconductor layer 115 of a second conductivity type are sequentially stacked. The first epitaxial structure 110 may be a structure for blue light emission.

The second epitaxial structure 130 may include a structure in which a first semiconductor layer 131 of the first conductivity type, an active layer 133, and a second semiconductor layer 135 of the second conductivity type are sequentially stacked. The second epitaxial structure 130 may be a structure for green light emission.

The third epitaxial structure 150 may include a structure in which a first semiconductor layer 151 of the first conductivity type, an active layer 153, and a second semiconductor layer 155 of the second conductivity type are sequentially stacked. The third epitaxial structure 150 may be a structure for red light emission.

The first semiconductor layers 111, 131, and 151 may be doped to have the first conductivity type, and the second semiconductor layers 115, 135, and 155 may be doped to have the second conductivity type that is electrically opposite to the first conductivity type. For example, the first semiconductor layers 111, 131, and 151 may be doped to have an n type, the second semiconductor layers 115, 135, and 155 may be doped to have a p type, or the first semiconductor layers 111, 131, and 151 may be doped to have the p type, and the second semiconductor layers 115, 135 and 155 may be doped to have the n type. One from among the first semiconductor layers 111, 131, 151 and the second semiconductor layers 115, 135, and 155 may be a group III-V compound semiconductor layer doped to have the n type and the other may be a group III-V compound semiconductor layer doped to have the p type.

The active layers 113, 133, and 153 may recombine electrons and holes provided from the first semiconductor layers 111, 131, and 151 and the second semiconductor layers 115, 135, and 155 to generate light. To this end, the active layers 113, 133, and 153 may have a quantum well structure in which a quantum well is arranged between the barriers. The wavelength of light generated from the active layers 113, 133, and 153 may be determined according to the energy band gap of the material constituting the quantum well in the active layers 113, 133, and 153. The active layers 113, 133, and 153 may have only a single quantum well, but may have a multi-quantum well (MQW) structure in which a plurality of quantum wells are arranged. The energy of the quantum well in the conduction band may be selected to be less than the energy of the barrier. To this end, the barriers and quantum wells in the active layers 113, 133, and 153 may include different compound semiconductors or compound semiconductors having different compositions.

The first semiconductor layers 111, 131, and 151, the active layers 113, 133, and 153, and the second semiconductor layers 115, 135 and 155 may include, for example, a group III-V compound semiconductor based on GaN. For example, the first semiconductor layers 111, 131, and 151, the active layers 113, 133, and 153, and the second semiconductor layers 115, 135 and 155 may include a group III-V compound semiconductor such as GaN, InGaN, AlInGaN and AlGaInP, and the first semiconductor layers 111, 131, and 151 and the second semiconductor layers 115, 135 and 155 may be doped to have a conductivity type opposite to each other.

For example, the first semiconductor layer 111, 131, and 151 and the second semiconductor layers 115, 135 and 155 may include GaN, and may be doped to have a conductivity type opposite to each other. That is, the first semiconductor layers 111, 131, and 151 may include a GaN layer doped with the n type and the second semiconductor layers 115, 135 and 155 may include a GaN layer doped with the p type. As another example, the first semiconductor layers 111, 131, and 151 may include a GaN layer doped with the p type, and the second semiconductor layers 115, 135 and 155 may include a GaN layer doped with the n type. The active layers 113, 133, and 153 may include, for example, InGaN and a composition ratio of In and Ga may vary according to a desired emission wavelength.

In each of the first epitaxial structure 110, the second epitaxial structure 130 and the third epitaxial structure 150, the active layers 113, 133, and 153 may have, for example, a stacked structure of a first barrier, a quantum well, and then a second barrier. The first barrier may be, for example, a GaN barrier, in which Si may or may not be doped. The quantum well may have a single quantum well structure or a multi-quantum well structure. For example, the quantum well may include a single stack structure or a plurality of stack structures of InGaN/GaN or InGaN/GaN/AlGaN. In InₓGa₁₋ₓN of the stacked structure forming the quantum well, the composition ratio of In and Ga may vary depending on the emission wavelength. GaN of the stacked structure forming the quantum well may or may not be doped with Si.

For example, when the first epitaxial structure 110, the second epitaxial structure 130, and the third epitaxial structure 150 generate blue light, green light, and red light, respectively, the active layer 133 of the second epitaxial structure 130 and the active layer 153 of the third epitaxial structure 150 may or may not include AlGaN and the active layer 113 of the first epitaxial structure 110 may not include AlGaN. That is, in the active layer 133 of the second epitaxial structure 130 and the active layer 153 of the third epitaxial structure 150, the quantum well may include a single stack structure or a plurality of stack structures of InₓGa₁₋ₓN/GaN or InₓGa₁₋ₓN/GaN/AlGaN, and in the active layer 113 of the first epitaxial structure 110, the quantum well may include a single stack structure or a plurality of stack structures of InₓGa₁₋ₓN/GaN.

The first intermediate layer 120 provided between the first epitaxial structure 110 and the second epitaxial structure 130 may include a contact region 120a in contact with the first p-type electrode 117. The first intermediate layer 120 may be less thick in a direction (e.g., Z direction) perpendicular to an extending direction of the first epitaxial structure 110 in the contact region 120a than in a region of the first intermediate layer 120 that is not in contact with the first p-type electrode 117.

The first intermediate layer 120 may include AlGaN. The first intermediate layer 120 may have a selectivity, and thus, may function as an etching stop layer. In other words, due to the difference in the etching rate between the first intermediate layer 120 and the first semiconductor layer 131 provided on the first intermediate layer 120, the first intermediate layer 120 may function as an etching stop layer when etching is performed to form the first via hole 160.

A two-dimensional electron gas (2DEG) layer may be formed between the first intermediate layer 120 and the second semiconductor layer 115. The 2DEG layer may exhibit very high electron mobility.

The second intermediate layer 121 provided between the second epitaxial structure 130 and the third epitaxial structure 150 may include a contact region 121a in contact with the second p-type electrode 137. The second intermediate layer 121 may be less thick in a direction (z direction) perpendicular to the second epitaxial structure 130 in the contact region 121a than in a region of the second intermediate layer 121 that is not in contact with the second p-type electrode 137.

A 2DEG layer may be formed between the second intermediate layer 121 and the second semiconductor layer 135. The 2DEG layer may exhibit very high electron mobility.

The second intermediate layer 121 may include AlGaN. The second intermediate layer 121 may have a selectivity, and thus, may function as an etching stop layer. In other words, due to the difference in the etching rate between the second intermediate layer 121 and the first semiconductor layer 151 provided on the second intermediate layer 121, the second intermediate layer 121 may function as an etching stop layer when etching is performed to form the second via hole 161.

The first via hole 160 provided through a portion of the second epitaxial structure 130 and a portion of the third epitaxial structure 150 may be filled with the first p-type electrode 117. The first p-type electrode 117 may be provided to be in contact with the first intermediate layer 120. The first p-type electrode 117 may include at least one material selected from among Au, Cu, Ni, Ag, Cr, W, Al, Pt, Sn, Pb, Fe, Ti, and Mo, or may include any one from among ITO, ZrB, ZnO, InO, and SnO.

The second via hole 161 provided through a portion of the third epitaxial structure 150 may be filled with the second p-type electrode 137. The second p-type electrode 137 may be provided to be in contact with the second intermediate layer 121. The second p-type electrode 137 may include at least one material from among Au, Cu, Ni, Ag, Cr, W, Al, Pt, Sn, Pb, Fe, Ti, and Mo, or may include any one from among ITO, ZrB, ZnO, InO, and SnO.

The light emitting device 100 may further include a first insulating layer 118 provided to surround the sidewall of the first p-type electrode 117, and a second insulating layer 138 provided to surround the sidewall of the second p-type electrode 137. The first insulating layer 118 may insulate the first p-type electrode 117 from the second epitaxial structure 130 and the third epitaxial structure 150. The second insulating layer 138 may insulate the second p-type electrode 137 from the third epitaxial structure 150. The first insulating layer 118 and the second insulating layer 138 may include an insulating material. The first insulating layer 118 and the second insulating layer 138 may include, for example, SiO₂, Si₃N₄, HfO₂, or Al₂O₃.

A third p-type electrode 157 may be provided on a portion of the third epitaxial structure 150. The third p-type electrode 157 may include at least one material from among Au, Cu, Ni, Ag, Cr, W, Al, Pt, Sn, Pb, Fe, Ti, and Mo, or may include any one from among ITO, ZrB, ZnO, InO, and SnO.

A first passivation layer 168 may be provided on the third epitaxial structure 150. The first passivation layer 168 may serve to protect the epitaxial structure from external physical and chemical impacts and insulate the epitaxial structure to prevent leakage of current.

A reflective electrode 170 may be provided on the first passivation layer 168. Light may be partially emitted to the outside of the light emitting device 100 after the orientation direction is changed through the reflective electrode 170. In this way, when the reflective electrode 170 is further included, light efficiency may be improved because the traveling direction of light that does not travel in the initial orientation direction may be changed to the orientation direction.

A first pad electrode 171, a second pad electrode 173, and a third pad electrode 175 may be provided on the first p-type electrode 117, the second p-type electrode 137, and the third p-type electrode 157, respectively. The first p-type electrode 117, the second p-type electrode 137, and the third p-type electrode 157 may be connected to the first pad electrode 171, the second pad electrode 173, and the third pad electrode 175, respectively. A gap fill layer 178 may be filled between the first p-type electrode 117, the second p-type electrode 137, the third p-type electrode 157, and the reflective electrode 170. The gap fill layer 178 may include, for example, SiO₂.

The backplane 301 may be provided on the first pad electrode 171, the second pad electrode 173, and the third pad electrode 175. The backplane 301 may include the driving layer 320 for driving the light emitting device 100, and the substrate 330 for supporting the driving layer 320.

The substrate 330 may include an insulating material such as glass, an organic polymer, crystal, and the like. In addition, the substrate 330 may include a flexible material having flexibility to be bent or folded, and may have a single-layer structure or a multi-layer structure.

The driving layer 320 may include a buffer layer 321 arranged on the substrate 330, and a transistor arranged on the buffer layer 321. The driving layer 320 may further include a driving voltage line, a scan driving unit, a data driving unit, and a processor.

The buffer layer 321 may prevent diffusion of impurities into the transistor. The buffer layer 321 may be provided as a single layer, but may be provided as at least a double layer or multiple layers. When the buffer layer 321 is provided as multiple layers, each layer may include a same material or may include different materials. The buffer layer 321 may be omitted depending on the material and process conditions of the substrate 330.

Transistors (e.g., a first transistor TR1, a second transistor TR2, and a third transistor TR3) may drive a corresponding epitaxial structure among a plurality of epitaxial structures included in a display layer. For example, the driving layer 320 may include a first transistor TR1 driving the first epitaxial structure 110, a second transistor TR2 driving the second epitaxial structure 130, and a third transistor TR3 driving the third epitaxial structure 150. Each of the transistors (e.g., the first transistor TR1, the second transistor TR2, and the third transistor TR3) may include a semiconductor layer SC, a gate electrode G, a source electrode S, and a drain electrode D.

The semiconductor layer SC may be arranged on the buffer layer 321. The semiconductor layer SC may include a source region in contact with the source electrode S and a drain region in contact with the drain electrode D. A region between the source region and the drain region may be a channel region.

The semiconductor layer SC may be a semiconductor pattern made of polysilicon, amorphous silicon, oxide semiconductor, or the like. The channel region may be a semiconductor pattern that is not doped with impurities, and may be an intrinsic semiconductor. The source region and the drain region may be semiconductor patterns doped with impurities.

The gate electrode G may be provided on the semiconductor layer SC with the gate insulating layer 322 therebetween.

Each of the source electrode S and the drain electrode D may be in contact with the source region and the drain region of the semiconductor layer SC through a contact hole penetrating the interlayer insulating layer 323 and the gate insulating layer 322.

A protection layer 324 may be provided on the transistors (e.g., the first transistor TR1, the second transistor TR2, and the third transistor TR3). The protective layer may include conductive vias (e.g., a first conductive via CV1, a second conductive via CV2, and a third conductive via CV3). The first p-type electrode 117 may be electrically connected to the first transistor TR1 (e.g., a drain of the first transistor TR1) through a first conductive via CV1, the second p-type electrode 137 may be electrically connected to the second transistor TR2 (e.g., a drain of the second transistor TR2) through a second conductive via CV2, and the third p-type electrode 157 may be electrically connected to the third transistor TR3 (e.g., a drain of the third transistor TR3) through a third conductive via CV3.

An n-type electrode 180 may be provided to extend upward from a lower portion of the first epitaxial structure 110. That is, the n-type electrode 180 may be provided below the first epitaxial structure 110 and may extend toward the third epitaxial structure 150. The n-type electrode 180 may be referred to as an n-type common electrode. The n-type electrode 180 may be a transparent electrode. The n-type electrode 180 may include, for example, indium tin oxide (ITO).

A third insulating layer 188 surrounding the sidewall of the n-type electrode 180 may be provided. The third insulating layer 188 may include an insulating material. The third insulating layer 188 may include, for example, SiO₂, Si₃N₄, HfO₂, or Al₂O₃.

According to embodiments of the disclosure, a display device may include a monolithic light-emitting element with stacked Red (R), Green (G), and Blue (B) light sources, where n-type and p-type semiconductor electrodes are configured for each of the R/G/B light sources. To form the electrodes, via holes may be created through layers via a selective etching process. The selective etching process may be used to form the via holes for, in part, a p-type contact semiconductor layer, utilizing an etch-stop technique that ensures precise placement of the via holes. This p-type contact semiconductor layer may enable efficient current injection and enhance the light emitting performance of the display device. The AlGaN intermediate layer may contribute to stability and improved performance. Furthermore, a two-dimensional electron gas (2DEG) layer formed between the p-type semiconductor and the AlGaN intermediate layer may improve current diffusion and overall performance of the display device. For example, in the light emitting device 100 according to an embodiment, the first intermediate layer 120 and the first p-type electrode 117 may come in contact with each other, the second intermediate layer 121 and the second p-type electrode 137 may come in contact with each other, and 2DEG layers may be formed between the first intermediate layer 120 and the second semiconductor layer 115, and between the second intermediate layer 121 and the second semiconductor layer 135, respectively, thereby exhibiting excellent current diffusion, and the first intermediate layer 120 and the second intermediate layer 121 may function as an etching stop layer, thereby exhibiting stable process dispersion.

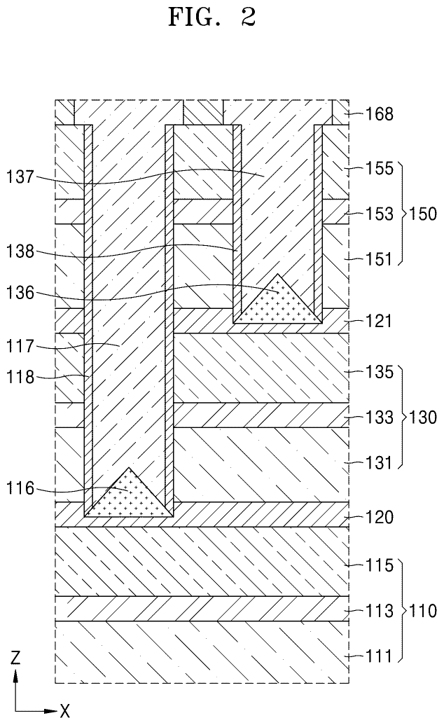

FIG. 2 is a cross-sectional view illustrating a modified example of a portion A of the light emitting device shown in FIG. 1.

Referring to FIG. 2, the light emitting device 100 may further include a first p-type contact semiconductor layer 116 provided in the contact region 120a in which the first intermediate layer 120 is in contact with the first p-type electrode 117, and a second p-type contact semiconductor layer 136 provided in the contact region 121a in which the second intermediate layer 121 is in contact with the second p-type electrode 137.

The first p-type contact semiconductor layer 116 may include a same material as a material of the second semiconductor layer 115, and the second p-type contact semiconductor layer 136 may include a same material as a material of the second semiconductor layer 135. Since the first p-type contact semiconductor layer 116 is provided, contact characteristics of the first p-type electrode 117 may be improved, and since the second p-type contact semiconductor layer 136 may be provided, contact characteristics of the second p-type electrode 137 may be improved.

The first p-type contact semiconductor layer 116 may be provided to recover plasma damage generated during the etching process of the first via hole 160, and the second p-type contact semiconductor layer 136 may be provided to recover plasma damage generated during the etching process of the second via hole 161.

In FIG. 2, the first p-type contact semiconductor layer 116 and the second p-type contact semiconductor layer 136 have pyramid shapes, but embodiments are not limited thereto and may have various other shapes.

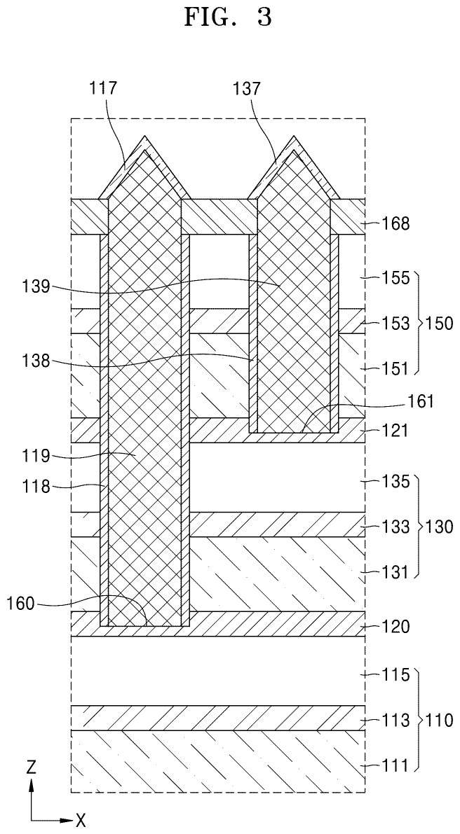

FIG. 3 is a cross-sectional view illustrating a modified example of the portion A of the light emitting device shown in FIG. 1.

Referring to FIG. 3, the light emitting device 100 may further include a first p-type contact semiconductor layer 119 provided to fill the first via hole 160 and a second p-type contact semiconductor layer 139 provided to fill the second via hole 161. The first p-type electrode 117 may be provided on the first p-type contact semiconductor layer 119, and the second p-type electrode 137 may be provided on the second p-type contact semiconductor layer 139.

The first intermediate layer 120 provided between the first epitaxial structure 110 and the second epitaxial structure 130 may be less thick in a direction (e.g., Z direction) perpendicular to the first epitaxial structure 110 in a region in contact with the first p-type contact semiconductor layer 119 than in a region of the first intermediate layer 120 which is not in contact with the first p-type contact semiconductor layer 119.

The second intermediate layer 121 provided between the second epitaxial structure 130 and the third epitaxial structure 150 may be less thick in a direction (e.g., Z direction) perpendicular to the first epitaxial structure 110 in a region in contact with the second p-type contact semiconductor layer 139 than in a region of the second intermediate layer 121 which is not in contact with the second p-type contact semiconductor layer 139.

The first p-type contact semiconductor layer 119 may include a same material as a material of the second semiconductor layer 115, and the second p-type contact semiconductor layer 139 may include a same material as a material of the second semiconductor layer 135. Process difficulty may be reduced by filling the first via hole 160 and the second via hole 161 with the first p-type contact semiconductor layer 119 and the second p-type contact semiconductor layer 139 instead of the electrode.

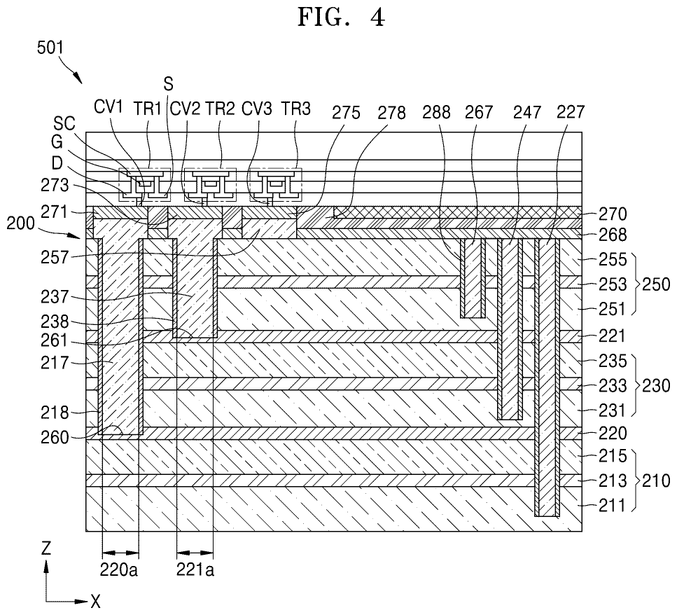

FIG. 4 is a cross-sectional view illustrating a display device according to an embodiment.

Referring to FIG. 4, a display device 501 may include a light emitting device 200, a driving layer 320 (see FIG. 1) for driving the light emitting device 200, and a substrate 330 (see FIG. 1) for supporting the driving layer 320.

The light emitting device 200 may include a first epitaxial structure 210, a second epitaxial structure 230, and a third epitaxial structure 250 that are sequentially stacked in a vertical direction, a first intermediate layer 220 provided between the first epitaxial structure 210 and the second epitaxial structure 230, a second intermediate layer 221 provided between the second epitaxial structure 230 and the third epitaxial structure 250, a first via hole 260 penetrating a portion of the second epitaxial structure 230 and a portion of the third epitaxial structure 250, a second via hole 261 penetrating a portion of the third epitaxial structure 250, a first p-type electrode 217 provided to fill the first via hole 260, a second p-type electrode 237 provided to fill the second via hole 261, and a third p-type electrode 257 provided on the third epitaxial structure 250.

Like the first p-type electrode 217, the second p-type electrode 237, and the third p-type electrode 257, the light emitting device 200 may include a first n-type electrode 227, a second n-type electrode 247, and a third n-type electrode 267 provided to extend downward from the top of the third epitaxial structure 250. That is, the first n-type electrode 227, the second n-type electrode 247, and the third n-type electrode 267 may be provided from the top of the third epitaxial structure 250 such as to extend toward the first epitaxial structure 210.

The first n-type electrode 227 may be provided through a portion of the third epitaxial structure 250, the second n-type electrode 247 may be provided through a portion of the second epitaxial structure 230 and a portion of the third epitaxial structure 250, and the third n-type electrode 267 may be provided through a portion of the first epitaxial structure 210, a portion of the second epitaxial structure 230, and a portion of the third epitaxial structure 250.

The first n-type electrode 227, the second n-type electrode 247, and the third n-type electrode 267 may be transparent electrodes. The first n-type electrode 227, the second n-type electrode 247, and the third n-type electrode 267 may include, for example, ITO.

The display device 501 of FIG. 4 may be the same as the display device 500 of FIG. 1, except that the first n-type electrode 227, the second n-type electrode 247, and the third n-type electrode 267 are provided to extend downward from the top of the third epitaxial structure 250. In describing FIG. 4, redundant descriptions of FIG. 1 may be omitted.

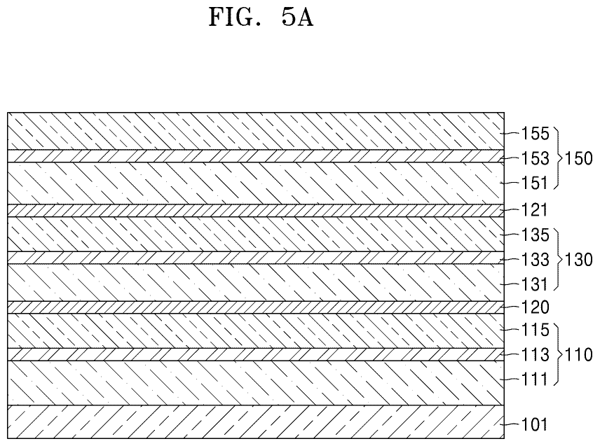

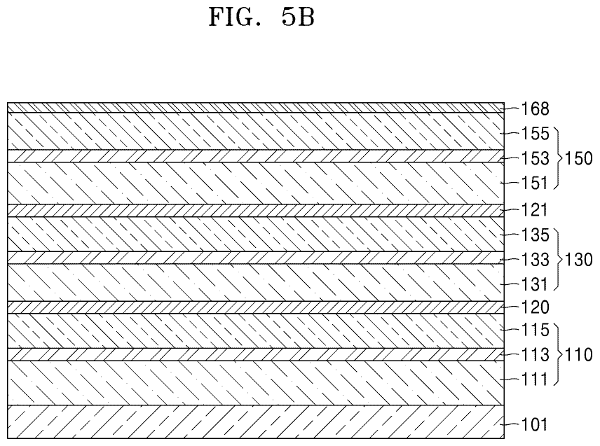

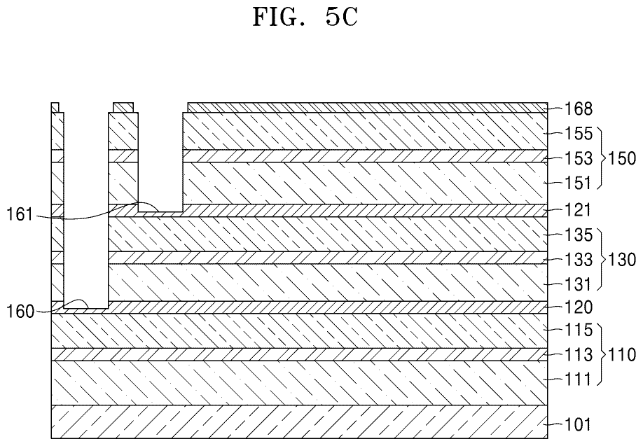

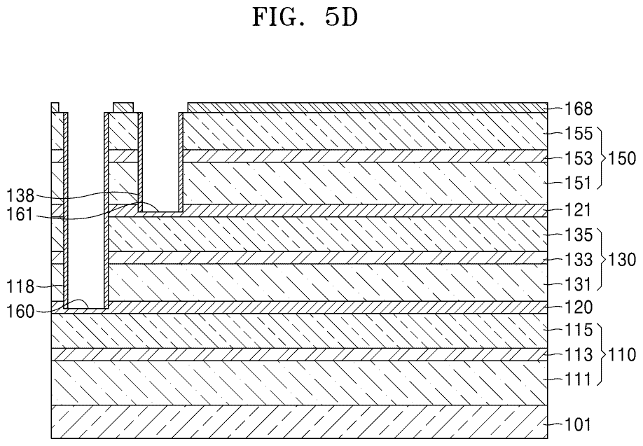

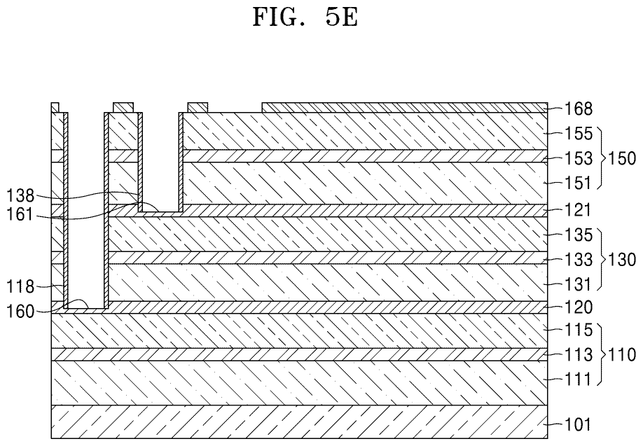

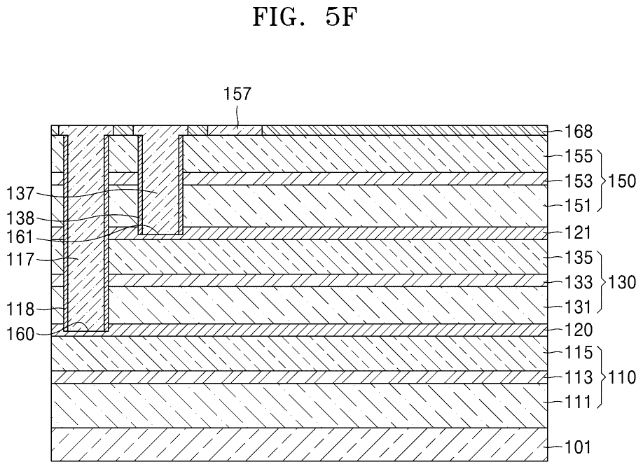

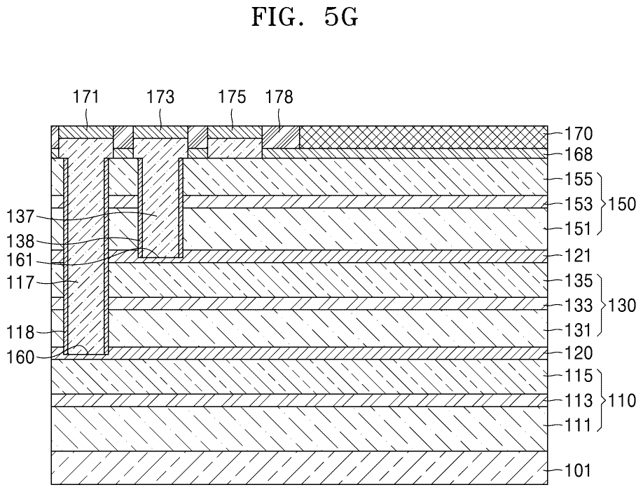

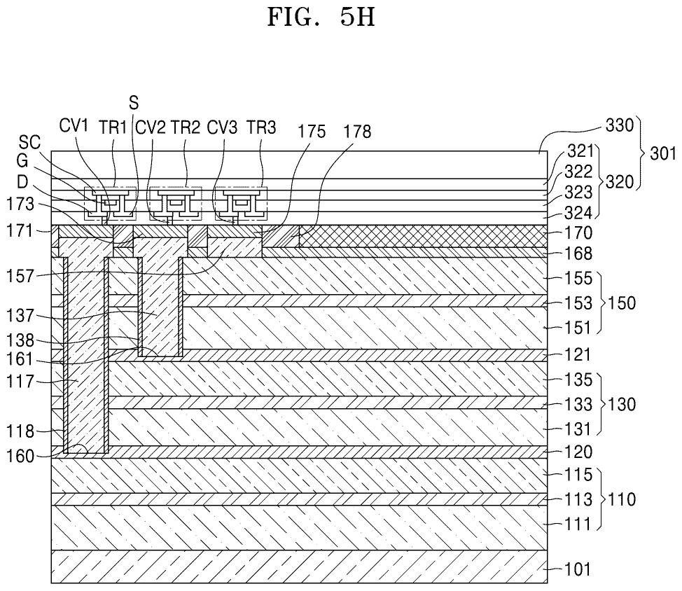

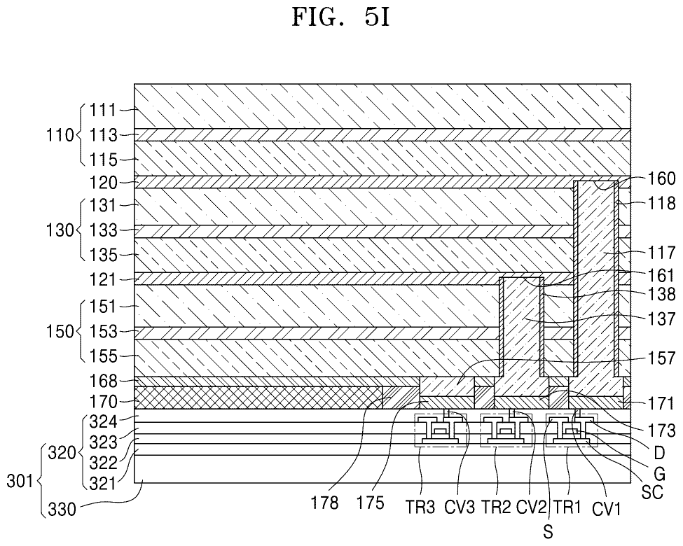

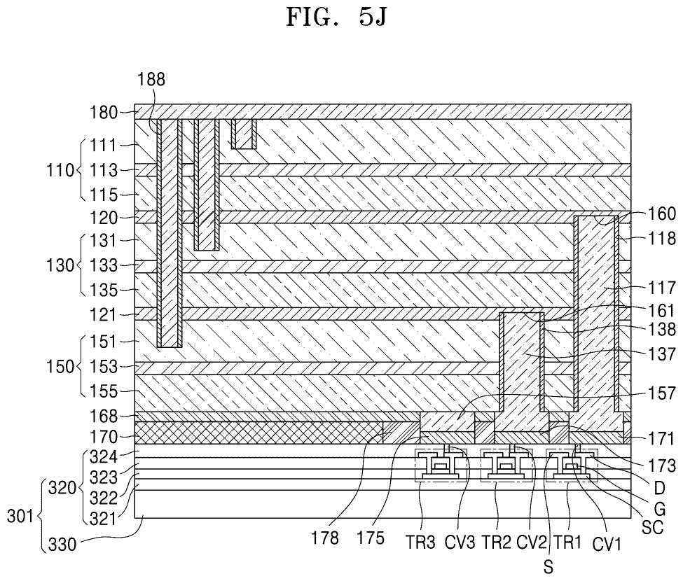

FIGS. 5A to 5J are cross-sectional views illustrating a method of manufacturing a display device according to an embodiment. In describing FIGS. 5A to 5J, redundant descriptions of FIG. 1 may be omitted.

Referring to FIG. 5A, a light emitting structure in which a first epitaxial structure 110, a second epitaxial structure 130, and a third epitaxial structure 150 are vertically stacked to generate light of different wavelengths may be formed on a growth substrate 101.

That is, a plurality of epitaxial structures for color light emission may be sequentially stacked on the growth substrate 101. For example, a vertical stacked epitaxial structure may be formed by sequentially stacking the first epitaxial structure 110 for first color light emission on the growth substrate 101, the second epitaxial structure 130 for second color light emission on the first epitaxial structure 110, and the third epitaxial structure 150 for third color light emission on the second epitaxial structure 130. For example, one from among the first color light, the second color light, and the third color light may be red light, another may be green light, and the other may be blue light. In the present embodiment, an example in which color implementation of the display device is performed through first to third color light emission is shown, but embodiments are not limited thereto. The number of epitaxial structures to be stacked may vary according to the number of color lights for color implementation. Hereinafter, a process of manufacturing a display device implementing a color display through first to third color light emission is described.

The growth substrate 101 may include, for example, silicon, sapphire, or GaAs. However, embodiments are not limited thereto and the growth substrate 101 may include a material other than silicon, sapphire, or GaAs. A buffer layer may be provided between the growth substrate 101 and the first epitaxial structure 110 to relieve stress caused by a difference in lattice constant between the growth substrate 101 and a first semiconductor layer 111 of the first epitaxial structure 110. The buffer layer may be grown to have a crystalline quality using, for example, a chemical vapor deposition (CVD) process, a physical vapor deposition (PVD) process, or an atomic layer deposition (ALD) process. The lattice constant of the buffer layer may have a value between the lattice constant of the growth substrate 101 and the lattice constant of the first semiconductor layer 111, or may have the same value as the lattice constant of the first semiconductor layer 111.

The buffer layer may include, for example, a group III-V compound semiconductor such as GaN, GaP, GaAs, or the like. In addition, the buffer layer may be doped with the same conductivity type as the first semiconductor layer 111. For example, if the first semiconductor layer 111 is doped to be an n-type, the buffer layer may also be doped to be an n-type, and if the first semiconductor layer 111 is doped in be a p-type, the buffer layer may also be doped to be a p-type.

Referring to FIGS. 5B and 5C, after the first passivation layer 168 is formed on the third epitaxial structure 150, a portion of the second epitaxial structure 130 and a portion of the third epitaxial structure 150 may be etched to form the first via hole 160, and a portion of the third epitaxial structure 150 may be etched to form the second via hole 161. The etching process for forming the first via hole 160 and the second via hole 161 may be a dry etching process.

Referring to FIGS. 5D and 5E, a portion of the first passivation layer 168 may be etched after forming the first insulating layer 118 provided to surround the sidewalls of the first via hole 160 and the second insulating layer 138 provided to surround the sidewalls of the second via hole 161.

Referring to FIG. 5F, the first p-type electrode 117 provided to fill the first via hole 160, the second p-type electrode 137 provided to fill the second via hole 161, and the third p-type electrode 157 provided to fill the first passivation layer 168 partially etched in FIG. 5E may be formed.

Referring to FIG. 5G, a gap fill layer 178 may be formed on the upper portions of the first p-type electrode 117, the second p-type electrode 137, the third p-type electrode 157, and the first passivation layer 168, and then a portion of the gap fill layer 178 may be etched. Thereafter, the first pad electrode 171, the second pad electrode 173, and the third pad electrode 175 may be formed on the first p-type electrode 117, the second p-type electrode 137, and the third p-type electrode 157, respectively, and the reflective electrode 170 may be formed on the first passivation layer 168.

Referring to FIG. 5H, the backplane 301 connected to the first pad electrode 171, the second pad electrode 173, and the third pad electrode 175 may be formed.

Referring to FIGS. 5I and 5J, the growth substrate 101 may be removed, and an n-type electrode 180 extending from the first epitaxial structure 110 toward the third epitaxial structure 150 may be formed.

In the method of manufacturing a display device according to an embodiment, in the etching process of forming the first via hole 160 and the second via hole 161, the first intermediate layer 120 and the second intermediate layer 121 may function as an etching stop layer, so that the dispersion of the process is stable.

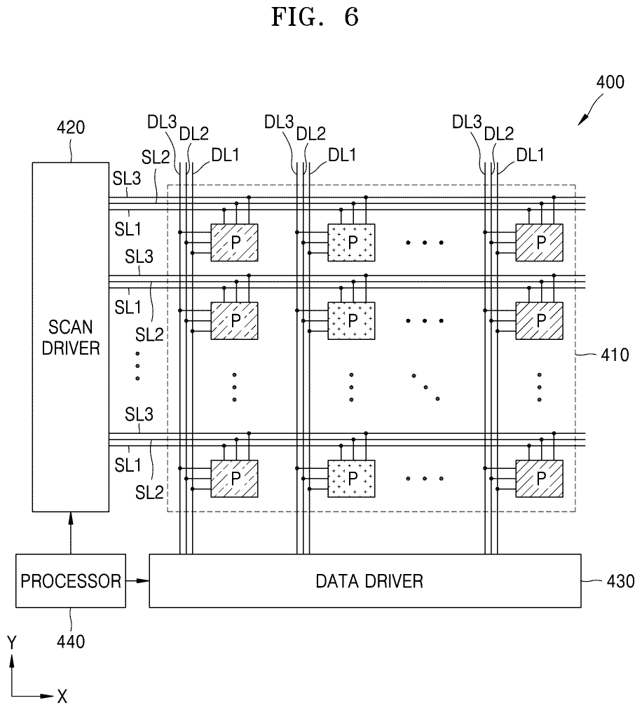

FIG. 6 is a block diagram illustrating a schematic configuration of a display device according to an embodiment.

Referring to FIG. 6, a display device 400 may include a pixel array 410, a scan driver 420, a data driver 430, and a processor 440. The pixel array 410 may include a plurality of pixels P arranged in a two-dimensional array form, a plurality of scan line sets for transmitting a scan signal to the plurality of pixels P, and a plurality of data line sets for transmitting a data signal to the plurality of pixels P. At least one from among the plurality of pixels P of the pixel array 410 may include the light emitting devices 100 and 200 described above.

Each of the scan line sets may include a first scan line SL1, a second scan line SL2, and a third scan line SL3 extending in the X direction. Each of the first scan line SL1, the second scan line SL2, and the third scan line SL3 may be connected to the plurality of pixels P arranged in the X direction. For example, the first scan line SL1 may be electrically connected to the gate electrode of the first transistor in each pixel P, the second scan line SL2 may be electrically connected to the gate electrode of the second transistor in each pixel P, and the third scan line SL3 may be electrically connected to the gate electrode of the third transistor in each pixel P. The first scan line SL1, the second scan line SL2, and the third scan line SL3 may also be connected to the scan driver 420 to receive a scan signal from the scan driver 420.

Each of the data line sets may include a first data line DL1, a second data line DL2, and a third data line DL3 extending in the Y direction. Each of the first data line DL1, the second data line DL2, and the third data line DL3 may be connected to the plurality of pixels P arranged in the Y direction. For example, the first data line DL1 may be electrically connected to the source horizontal line of the first transistor in each pixel P, the second data line DL2 may be electrically connected to the source horizontal line of the second transistor in each pixel P, and the third data line DL3 may be electrically connected to the source horizontal line of the third transistor in each pixel P. The first data line DL1, the second data line DL2, and the third data line DL3 may also be connected to the data driver 430 to receive a data signal from the data driver 430.

The processor 440 may adjust the scan signal and the data signal provided to each pixel P by controlling the operations of the scan driver 420 and the data driver 430 based on the data of the image to be displayed in the pixel array 410.

In the display device 400 described above, one pixel providing all of blue light, green light, and red light may be formed with only one light emitting device. Accordingly, the display device 400 may provide an ultra-high resolution image. The display device 400 may be applied to various electronic devices having a screen display function.

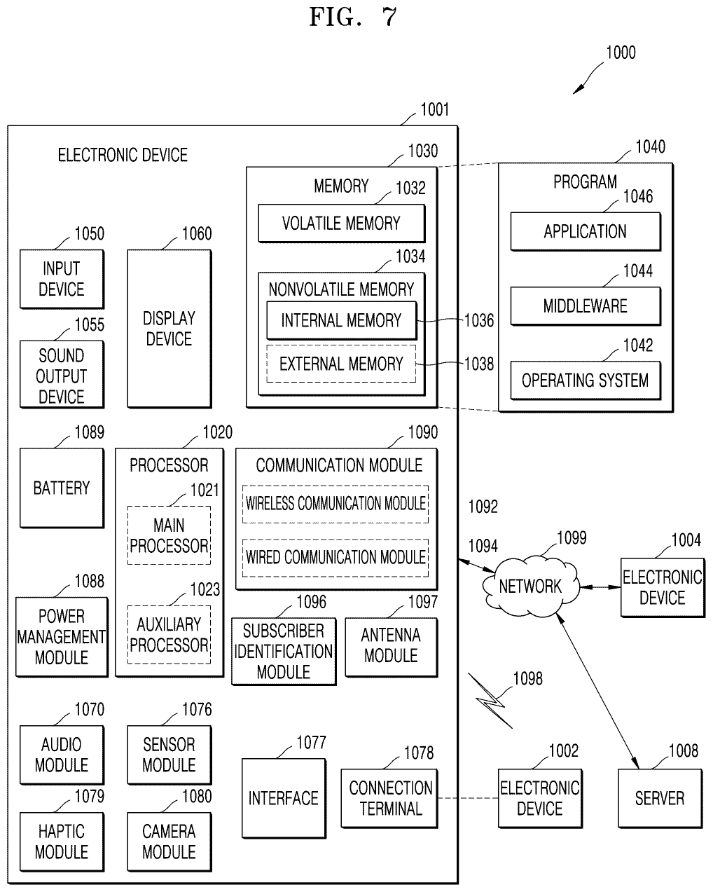

FIG. 7 is a schematic block diagram of an electronic device according to an embodiment.

Referring to FIG. 7, an electronic device 1001 may be provided in a network environment 1000. In the network environment 1000, the electronic device 1001 may communicate with another electronic device 1002 through the first network 1098 (e.g., a short-range wireless communication network, etc.), or with another electronic device 1004 and/or the server 1008 through the second network 1099 (e.g., a long-distance wireless communication network, etc.). The electronic device 1001 may communicate with the electronic device 1004 through the server 1008. The electronic device 1001 may include a processor 1020, a memory 1030, an input device 1050, a sound output device 1055, a display device 1060, an audio module 1070, a sensor module 1076, an interface 1077, a haptic module 1079, a camera module 1080, a power management module 1088, a battery 1089, a communication module 1090, a subscriber identification module 1096 and/or an antenna module 1097. Some of these components may be omitted from the electronic device 1001 or other components may be added to the electronic device 1001. Some of these components may be implemented as one integrated circuit. For example, the sensor module 1076 (e.g., fingerprint sensor, iris sensor, illuminance sensor, etc.) may be implemented by being embedded in the display device 1060 (display, etc.).

The processor 1020 may execute software (e.g., program 1040 or the like) to control one or a plurality of other components (e.g., hardware and software components, or the like) of the electronic device 1001 connected to the processor 1020 and may perform processing or operations of various data. As part of data processing or operation, the processor 1020 may load commands and/or data received from other components (e.g., the sensor module 1076, the communication module 1090, etc.), process commands and/or data stored in volatile memory 1032 and store the result data in nonvolatile memory 1034. The nonvolatile memory 1034 may include an internal memory 1036 mounted in the electronic device 1001 and an external memory 1038 that is detachable. The processor 1020 may include a main processor 1021 (e.g., a central processing unit, an application processor, etc.) and an auxiliary processor 1023 (a graphics processing unit, an image signal processor, a sensor hub processor, a communication processor, etc.) that may be operated independently of or together with the main processor 1021. The auxiliary processor 1023 may use less power than the main processor 1021 and perform a specialized function.

The auxiliary processor 1023 may control functions and /r states related to some (e.g., the display device 1060, sensor module 1076, communication module 1090, etc.) of the components of the electronic device 1001, in place of the main processor 1021 while the main processor 1021 is in an inactive state (e.g., slip state), or together with the main processor 1021 while the main processor 1021 is in an active state (e.g., application execution state). The auxiliary processor 1023 (e.g., image signal processor, communication processor, etc.) may be implemented as part of other functionally related components (e.g., camera module 1080, communication module 1090, etc.).

The memory 1030 may store various data used by components (e.g., processor 1020 and sensor module 1076) of the electronic device 1001. The data may include, for example, input data and/or output data for software (e.g., program 1040 or the like) and related commands. The memory 1030 may include a volatile memory 1032 and/or a nonvolatile memory 1034.

The program 1040 may be stored in the memory 1030 as software and may include an operating system 1042, middleware 1044 and/or an application 1046.

The input device 1050 may receive commands and/or data to be used in components (e.g., processor 1020, etc.) of the electronic device 1001 from the outside (e.g., user, etc.) of the electronic device 1001. The input device 1050 may include a remote controller. a microphone, a mouse, a keyboard and/or a digital pen (e.g., a stylus pen, etc.).

The sound output device 1055 may output the sound signal to the outside of the electronic device 1001. The sound output device 1055 may include a speaker and/or a receiver. Speakers may be used for general purposes such as multimedia playback or recording playback and receivers may be used to receive incoming calls. The receiver may be coupled as part of a speaker or may be implemented as an independent separate device.

The display device 1060 may visually provide information to the outside of the electronic device 1001. The display device 1060 may include a display, a hologram device, or a projector and a control circuit for controlling the corresponding devices. The display device 1060 may include one of the display devices 500 and 501 according to the embodiments described above. The display device 1060 may further include touch circuitry configured to sense a touch and/or a sensor circuit (e.g., a pressure sensor, etc.) configured to measure an intensity of a force generated by the touch.

The audio module 1070 may convert sound into an electrical signal or conversely convert the electrical signal into sound. The audio module 1070 may acquire sound through the input device 1050 or output sound through the sound output device 1055 and/or a speaker and/or a headphone of another electronic device (e.g., electronic device 1002, etc.) directly or wirelessly connected to the electronic device 1001.

The sensor module 1076 may detect an operating state (e.g., power, temperature, etc.) or an external environmental state (e.g., user state, etc.) of the electronic device 1001 and generate an electrical signal and/or a data value corresponding to the sensed state. The sensor module 1076 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 1077 may support one or more designated protocols that may be used for electronic device 1001 to be directly or wirelessly connected to another electronic device (e.g., electronic device 1002, etc.). The interface 1077 may include a high definition multimedia interface (HDMI), a universal serial bus (USB) interface, a secure digital (SD) card interface and/or an audio interface.

The connection terminal 1078 may include a connector through which the electronic device 1001 may be physically connected to another electronic device (e.g., electronic device 1002, etc.). The connection terminal 1078 may include an HDMI connector, a USB connector, an SD card connector and/or an audio connector (e.g., a headphone connector, etc.).

The haptic module 1079 may convert an electrical signal to a mechanical stimulus (e.g., vibration, motion, etc.) or an electrical stimulus that a user can recognize through a tactile or motion sensation. The haptic module 1079 may include a motor, a piezoelectric element and/or an electrical stimulus.

The camera module 1080 may capture a still image and a moving image. The camera module 1080 may include a lens assembly including one or more lenses, image sensors, image signal processors and/or flashes. The lens assembly included in the camera module 1080 may collect light emitted from a subject that is a target of image capturing.

The power management module 1088 may manage power supplied to the electronic device 1001. The power management module 1088 may be implemented as part of a power management integrated circuit (PMIC).

The battery 1089 may supply power to components of the electronic device 1001. The battery 1089 may include a non-rechargeable primary battery, a rechargeable secondary battery, and/or a fuel cell.

The communication module 1090 may establish a direct (e.g., wired) communication channel and/or wireless communication channel between the electronic device 1001 and another electronic device (e.g., the electronic device 1002, the electronic device 1004, the server 1008, etc.) and support communication execution through the established communication channel. The communication module 1090 may include one or more communication processors that operate independently of the processor 1020 (e.g., application processor, etc.) and support direct communication and/or wireless communication. The communication module 1090 may include a wireless communication module 1092 (e.g., a cellular communication module, a short-range wireless communication module, a Global Navigation Satellite System (GNSS), etc., communication module and/or a wired communication module 1094 (e.g., a local area network (LAN) communication module, a power line communication module, etc.). A corresponding communication module of these communication modules may communicate with other electronic devices through a first network 1098 (e.g., a short-range communication network such as Bluetooth, WiFi Direct, or infrared data association (IrDA)), or a second network 1099 (e.g., a long-range communication network such as a cellular network, Internet, or computer network (LAN, WAN, etc.)). These various types of communication modules may be integrated into a single component (e.g., a single chip, etc.), or may be implemented as a plurality of separate components (e.g., multiple chips). The wireless communication module 1092 may identify and authenticate the electronic device 1001 in a communication network such as the first network 1098 and/or the second network 1099 using subscriber information (e.g., an international mobile subscriber identifier (IMSI)) stored in the subscriber identification module 1096.

The antenna module 1097 may transmit a signal and/or power to the outside (e.g., another electronic device, etc.) or receive the signal and/or power from the outside. The antenna may include a radiator formed of a conductive pattern formed on the substrate (e.g., printed circuit board (PCB), etc.). The antenna module 1097 may include one or more antennas. When a plurality of antennas are included, an antenna suitable for a communication scheme used in a communication network such as the first network 1098 and/or the second network 1099 may be selected from among the plurality of antennas by the communication module 1090. A signal and/or power may be transmitted or received between the communication module 1090 and another electronic device through the selected antenna. Other components (e.g., a radio-frequency integrated circuit (RFIC), etc.) in addition to the antenna may be included as a part of the antenna module 1097.

Some of the components may be connected to each other and may exchange signals (e.g., commands, data, etc.) via a communication scheme (e.g., bus, General Purpose Input and Output (GPIO), Serial Peripheral Interface (SPI), Mobile Industry Processor Interface (MIPI), etc.) and can interchange signals (e.g., commands, data, etc.) between peripherals.

The command or data may be transmitted or received between the electronic device 1001 and the electronic device 1004 through the server 1008 connected to the second network 1099. Other electronic devices 1002 and 1004 may be the same or different types of devices as the electronic device 1001. All or some of the operations executed in the electronic device 1001 may be executed in one or more of the other electronic devices 1002 and 1004 and the server 1008. For example, when the electronic device 1001 needs to perform a function or service, it may request one or more other electronic devices to perform part or all of the function or service instead of executing the function or service on its own. One or more other electronic devices receiving the request may execute an additional function or service related to the request and transmit a result of the execution to the electronic device 1001. To this end, cloud computing, distributed computing, and/or client-server computing technology may be used.

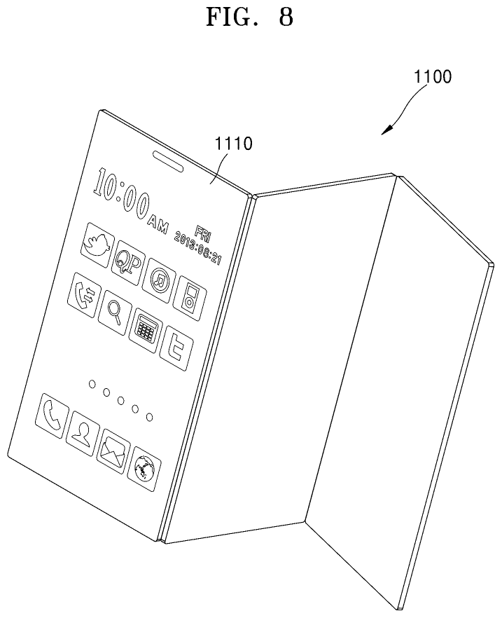

FIG. 8 illustrates an example in which a display device according to embodiments is applied to a mobile device.

Referring to FIG. 8, a mobile device 1100 may include a display device 1110, and the display device 1110 may include the display devices 500 and 501 according to the above-described embodiments. The display device 1110 may have a foldable structure such as, for example, a multi-foldable structure. Here, although it is illustrated that the mobile device 1100 includes a folder-type display, the mobile device 1100 may also include a flat-panel type display.

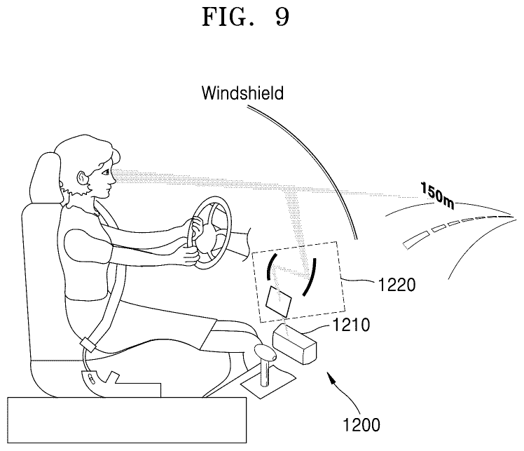

FIG. 9 illustrates an example in which a display device according to embodiments is applied to a display device for a vehicle.

Referring to FIG. 9, a display device may be a head-up display device 1200 for a vehicle, and may include a display 1210 provided in one area of the vehicle, and an optical path change member 1220 that converts an optical path so that the driver may see the image generated by the display 1210. The display 1210 may include any of the display devices 500 and 501 according to the embodiments described above.

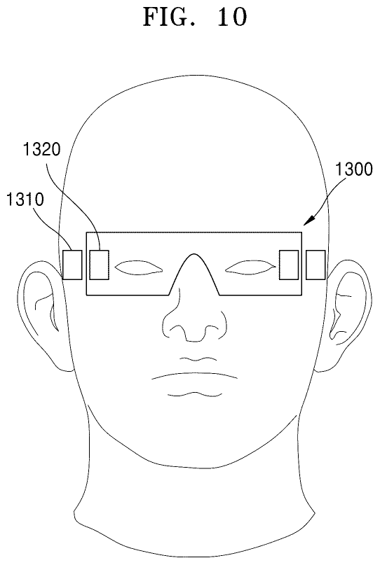

FIG. 10 illustrates an example in which a display device according to embodiments is applied to augmented reality glasses or virtual reality glasses.

Referring to FIG. 10, the augmented reality glasses 1300 may include a projection system 1310 forming an image and at least one element 1320 guiding an image from the projection system 1310 to enter the user's eye. The projection system 1310 may include any of the display devices 500 and 501 according to the above-described embodiments.

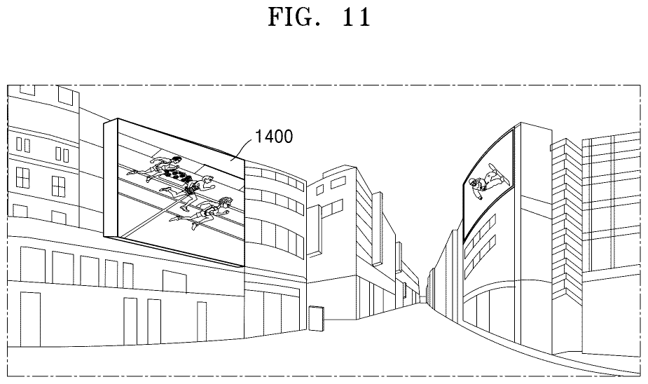

FIG. 11 illustrates an example in which a display device according to embodiments is applied to a signage.

Referring to FIG. 11, the signage 1400 may be used for outdoor advertisements using a digital information display and may control advertisement content, etc., through a communication network. The signage 1400 may be implemented through, for example, the electronic device described with reference to FIG. 7.

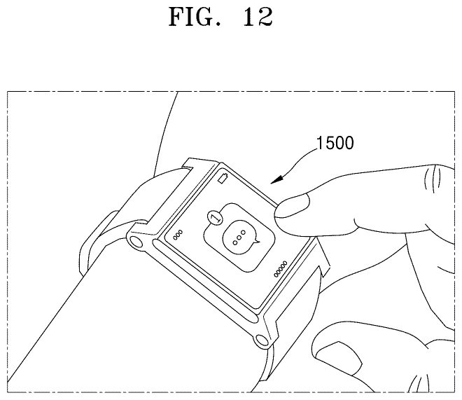

FIG. 12 illustrates an example in which a display device according to embodiments is applied to a wearable display.

Referring to FIG. 12, a wearable display 1500 may include any of the display devices 500 and 501 according to the above-described embodiments, and may be implemented through the electronic device described with reference to FIG. 7.

The display device according to an embodiment may be applied to various products such as a rollable TV and a stretchable display.

According to embodiments of the disclosure, a light emitting device with excellent current diffusion and a display device including the same may be provided as an intermediate layer and a p-type electrode come into contact with each other and a two-dimensional (2D) electron gas layer is formed between the intermediate layer and the semiconductor layer. The light emitting device and the display device including the same have been described with reference to example embodiments shown in the drawings. According to example embodiments of the disclosure, the 2D electron gas layer may be formed between the intermediate layer and the semiconductor layer to provide a light emitting device with excellent current diffusion and a display device including the same.

According to embodiments of the disclosure, a method of manufacturing a display device in which a process distribution is stable may be provided.

It should be understood that the example embodiments described herein should be considered in a descriptive sense only and not for purposes of limitation. Descriptions of features or aspects within each embodiment should typically be considered as available for other similar features or aspects in other embodiments of the disclosure. While one or more non-limiting example embodiments have been described with reference to the figures, it will be understood by those of ordinary skill in the art that various changes in form and details may be made therein without departing from the spirit and scope of the disclosure.

What is claimed is:

1. A light emitting device comprising:
a first epitaxial structure, a second epitaxial structure, and a third epitaxial structure that are sequentially stacked;
a first intermediate layer between the first epitaxial structure and the second epitaxial structure;
a second intermediate layer between the second epitaxial structure and the third epitaxial structure;
a first via hole penetrating the second epitaxial structure and the third epitaxial structure;
a second via hole penetrating the third epitaxial structure;
a first p-type electrode in the first via hole; and
a second p-type electrode in the second via hole,
wherein each of the first epitaxial structure, the second epitaxial structure, and the third epitaxial structure comprises a first semiconductor layer of a first conductivity type, an active layer, and a second semiconductor layer of a second conductivity type,
wherein the first epitaxial structure, the active layer, and the second semiconductor layer are sequentially stacked, and
wherein the first p-type electrode is in contact with the first intermediate layer, and the second p-type electrode is in contact with the second intermediate layer.

2. The light emitting device of claim 1, wherein the first intermediate layer has a first thickness in a first direction, perpendicular to an extending direction of the first epitaxial structure, in a contact region in which the first intermediate layer is in contact with the first p-type electrode, and
wherein the first thickness is less than a second thickness of the first intermediate layer in a region in which the first intermediate layer does not contact the first p-type electrode.

3. The light emitting device of claim 1, wherein the second intermediate layer has a first thickness in a first direction, perpendicular to an extending direction of the second epitaxial structure, in a contact region in which the second intermediate layer is in contact with the second p-type electrode, and
wherein the first thickness is less than a second thickness of the second intermediate layer in a region in which the second intermediate layer does not contact the second p-type electrode.

4. The light emitting device of claim 1, further comprising a p-type contact semiconductor layer, wherein the p-type contact semiconductor layer is in a contact region in which the first intermediate layer is in contact with the first p-type electrode.

5. The light emitting device of claim 4, wherein the p-type contact semiconductor layer comprises a material that is the same as a material of the second semiconductor layer of the first epitaxial structure.

6. The light emitting device of claim 1, further comprising a p-type contact semiconductor layer, wherein the p-type contact semiconductor layer is in a contact region in which the second intermediate layer is in contact with the second p-type electrode.

7. The light emitting device of claim 6, wherein the p-type contact semiconductor layer comprises a material that is the same as a material of the second semiconductor layer of the second epitaxial structure.

8. The light emitting device of claim 1, wherein the first intermediate layer and the second intermediate layer comprise AlGaN.

9. The light emitting device of claim 1, further comprising a third p-type electrode on the third epitaxial structure.

10. The light emitting device of claim 1, further comprising an n-type electrode extending upward from a lower portion of the first epitaxial structure.

11. The light emitting device of claim 1, further comprising an n-type electrode extending downward from an upper portion of the third epitaxial structure.

12. The light emitting device of claim 1, further comprising:
a first insulating layer surrounding a sidewall of the first p-type electrode; and
a second insulating layer surrounding a sidewall of the second p-type electrode.

13. A light emitting device comprising:
a first epitaxial structure, a second epitaxial structure, and a third epitaxial structure that are sequentially stacked;
a first intermediate layer between the first epitaxial structure and the second epitaxial structure;
a second intermediate layer between the second epitaxial structure and the third epitaxial structure;
a first via hole penetrating the second epitaxial structure and the third epitaxial structure;
a second via hole penetrating the third epitaxial structure;
a first p-type contact semiconductor layer in the first via hole; and
a second p-type contact semiconductor layer in the second via hole,
wherein each of the first epitaxial structure, the second epitaxial structure, and the third epitaxial structure comprises a first semiconductor layer of a first conductivity type, an active layer, and a second semiconductor layer of a second conductivity type,
wherein the first epitaxial structure, the active layer, and the second semiconductor layer are sequentially stacked, and
wherein the first p-type contact semiconductor layer is in contact with the first intermediate layer, and the second p-type contact semiconductor layer is in contact with the second intermediate layer.

14. The light emitting device of claim 13, wherein the first intermediate layer has a first thickness in a first direction, perpendicular to an extending direction of the first epitaxial structure, in a contact region in which the first intermediate layer is in contact with the first p-type contact semiconductor layer, and
wherein the first thickness is less than a second thickness of the first intermediate layer in a region in which the first intermediate layer is not in contact with the first p-type contact semiconductor layer.

15. The light emitting device of claim 13, wherein the second intermediate layer has a first thickness in a first direction, perpendicular to an extending direction of the second epitaxial structure, in a contact region in which the second intermediate layer is in contact with the second p-type contact semiconductor layer, and
wherein the first thickness is less than a second thickness of the second intermediate layer in a region in which the second intermediate layer is not in contact with the second p-type contact semiconductor layer.

16. The light emitting device of claim 13, further comprising:
a first p-type electrode on the first p-type contact semiconductor layer; and
a second p-type electrode on the second p-type contact semiconductor layer.

17. The light emitting device of claim 13, wherein the first intermediate layer and the second intermediate layer comprise AlGaN.

18. The light emitting device of claim 13, further comprising an n-type electrode extending upward from a lower portion of the first epitaxial structure.

19. A display device comprising:
a light emitting device comprising:
a first epitaxial structure, a second epitaxial structure, and a third epitaxial structure that are sequentially stacked;
a first intermediate layer between the first epitaxial structure and the second epitaxial structure;
a second intermediate layer between the second epitaxial structure and the third epitaxial structure;
a first via hole penetrating the second epitaxial structure and the third epitaxial structure;
a second via hole penetrating the third epitaxial structure;
a first p-type electrode in the first via hole; and
a second p-type electrode in the second via hole; and
a driving layer configured to drive the light emitting device,
wherein each of the first epitaxial structure, the second epitaxial structure, and the third epitaxial structure comprises a first semiconductor layer of a first conductivity type, an active layer, and a second semiconductor layer of a second conductivity type,
wherein the first epitaxial structure, the active layer, and the second semiconductor layer are sequentially stacked, and
wherein the first p-type electrode is in contact with the first intermediate layer, and the second p-type electrode is in contact with the second intermediate layer.

20. The display device of claim 19, further comprising a reflective electrode between the light emitting device and the driving layer.
